(19) United States
(12) Patent Application Publication
(10) Pub. No.: US 2011/0307200 A1
(43) Pub. Date: Dec. 15, 2011

(54) RECOGNIZING MULTIPLE APPLIANCE OPERATING STATES USING CIRCUIT-LEVEL ELECTRICAL INFORMATION

(75) Inventors: Chun-Nan Hsu, Taipei (TW); Jane Yung-Jen Hsu, Taipei (TW); Gu-Yuan Lin, Sanxia Township (TW); Shih-Chiang Lee, Daxi Township (TW)

(73) Assignee: Academia Sinica, Taipei (TW)

(21) Appl. No.: 13/157,387

(22) Filed: Jun. 10, 2011

Related U.S. Application Data
(60) Provisional application No. 61/353,847, filed on Jun. 11, 2010.

(51) Int. Cl. G06F 19/00; G01R 21/00

(52) U.S. Cl. 702/61

(57) ABSTRACT

An approach to measuring power consumption of multiple appliances adopts a transition probability to model the correlation and causality of appliance events caused by human behavior. The sequential order and relevance of using appliances can be taken into account. For instance, correlation between the use of (e.g., states of) different electrical appliances may be used.

### CROSS-REFERENCE TO RELATED APPLICATIONS

This application claims the benefit of U.S. Provisional Application No. 61/353,847 filed Jun. 11, 2010.

### BACKGROUND

This invention relates to recognizing multiple appliance operating states using circuit-level electrical information.

Due to the increasing cost of energy, environmental concerns, and safety concerns, energy-conservation is becoming an increasingly popular issue. Consequently, the use of smart energy meters to monitor energy usage is increasing. It is projected that within a few years, two hundred million smart meters will be installed in residences.

According to a 2008 Energy Information Administration report, residential buildings consume as much as 37% of the total power produced by electrical utilities. Some studies estimate that cost savings of approximately 5-15% are possible if consumers are given direct access to information about their energy consumption. However, most people lack this information and are thus unable to efficiently manage their power consumption.

Some preexisting power consumption meters employ appliance recognition techniques. These meters typically sense energy information using either smart outlets which measure energy information at each appliance or a power line interface which can capture pulses of electric events. Appliance recognition techniques can use the energy information collected by the meters to distinguish differences between a variety of appliances. This information can be used to provide detailed single appliance power consumption information to users. Armed with detailed knowledge of their power consumption, users can potentially eliminate unnecessary power usage by altering their appliance usage habits, replacing their appliances with high efficiency models, etc.

Sensor deployment for preexisting appliance recognition technologies may be an obstacle to the technologies being adopted by homeowners as at least one sensor is required for each appliance. This limitation increases the cost of system as well as the difficulty of maintaining the system. Furthermore, each sensor may require a power supply which can add to the overall power consumption of the household.

In some examples, power consumption information is used to provide energy-saving tips or advice for users. Furthermore, power consumption information can be used by automatic control systems to control the states of appliances such that power consumption is reduced.

### SUMMARY

A power consumption meter provides more detailed energy information for users and service providers. The meter minimizes the scope of sensor deployment by reducing the number of sensors required, the cost of maintenance, and the cost of installation. The meter is capable of detecting operating states of connected appliances in real time and providing services and energy conservation tips to users.

In some examples, the meters are installed at the circuit level and only on the electrical distribution board for the purpose of measuring total power consumption of a circuit. This eliminates the need for installing meters at each individual appliance. The reduced meter requirement results in simplified installation and maintenance of the metering system.

In some examples, the meter applies a Bayesian filtering approach to determine the most likely operating states of appliances connected to the meter. In particular, a dynamic Bayesian network accounts for user behavior and a Bayesian filter performs inference.

One or more approaches described herein provide advantages over previously published approaches as follows:

U.S. Pat. No. 4,858,141: Non-intrusive appliance monitor apparatus: The authors designed a non-intrusive appliance monitor apparatus for measuring the active power and reactive power from circuits to recognize the appliance states. They inferred the appliance states according to the transient change of power instead of the waveform; moreover, the patent did not consider the sequential order and relevance of using appliances.

U.S. Pat. No. 4,990,893: Method in alarm system, including recording of energy consumption: The inventors designed a residential alarm system for monitoring of service apartments for elderly and/or handicapped persons. The patent aimed to detected the abnormal events of energy consumption, not the appliance states.

U.S. Pat. No. 5,483,153: Transient event detector for use in non-intrusive load monitoring systems: Detecting the transient events in non-intrusive load monitoring systems for identifying each electrical load of appliances. The patent did not consider the sequential order and relevance of using appliances.

U.S. Pat. No. 5,717,325: Multiprocessing transient event detector for use in a nonintrusive electrical load monitoring system: Detecting the transient events in non-intrusive load monitoring systems and the decomposition of individual electrical load in which time scales are changed is completed in parallel. The patent did not consider the sequential order and relevance of using appliances.

U.S. Pat. No. 7,106,044: Systems, methods, and apparatuses for detecting residential electricity theft in firmware: After detecting a power outage upon removal of meter from the socket twice, identify residential electricity theft according to the electrical load. The patent aimed to detect electricity theft instead of appliance states and the authors did not consider the sequential order and relevance of using appliances.

S. Drenker and A. Kader, “Nonintrusive monitoring of electrical loads,” IEEE Comput. Appl. Power, vol. 12, no. 4, pp. 47-51, 1999: The authors detected the event of appliance state change between two different appliance states using difference of power. The proposed approach was difficult to distinguish two or more state combinations with similar total consumption. In addition, the authors did not take the sequential order and relevance of using appliances into account.

M. Ito, R. Uda, S. Ichimura, K. Tago, T. Hoshi, and Y. Matsushita, “A Method of Appliance Detection Based on Features of PowerWaveform,” Int. Symp. on Applications and the Internet, pp. 291-294, 2004: The authors extracted the feature values from the measured current values, such as average, peak, crest factor, form factor, and peak to average ratio, then stored all features values into database. The recognition method was to directly comparing the newly extracted feature values with those in database. However, their experiments did not verify the ability to recognize the case of using multiple appliances concurrently. Also, they did not consider the sequential order and relevance of using appliances.

Patel, S.; Robertson, T.; Kientz, J.; Reynolds, M. & Abowd, G. At the Flick of a Switch: Detecting and Classifying Unique Electrical Events on the Residential Power Line (Nominated for the Best Paper Award) Proceedings of the 9th International Conference on Ubiquitous Computing, 2007, 4717, 271-288: The authors used power line interface to capture the electric noise which is produced when changing appliance operating states. They took Fast Fourier Transform to extract features and performed support vector machine to recognize the appliance states. Nevertheless, the power line interface cannot obtain the power consumption and they did not consider the sequential order and relevance of using appliances.

Bauer, G.; Stockinger, K. & Lukowicz, P. Recognizing the Use-Mode of Kitchen Appliances from Their Current Consumption Smart Sensing and Context: 4th European Conference, EuroSSC 2009, Guildford, UK, Sep. 16-18, 2009. Proceedings, 2009, 5741, 163: The authors set specific decision rules for individual appliance; however, if there are some additional state combinations, they have to set extra decision rules manually. They did not take the sequential order and relevance of using appliances as well.

Kushiro, N.; Katsukura, M.; Nakata, M. & Ito, Y. Non-intrusive Human Behavior Monitoring Sensor for Health Care System Proceedings of the Symposium on Human Interface 2009 on Human Interface and the Management of Information. Information and Interaction. Part II: Held as part of HCl International 2009, 2009, 5618, 549-558: The authors used wavelet transformation to extract features of current values and computed the match ratio with features values in database to infer the appliance states. However, they did not consider the sequential order and relevance of using appliances.

Other features and advantages of the invention are apparent from the following description, and from the claims.

### DESCRIPTION OF DRAWINGS

FIG. 1 is a block diagram of the recognition algorithm.

FIG. 2 is a table of extracted features.

FIG. 3 is an exemplary dynamic Bayesian network model.

FIG. 4 is a table of appliances used in experiments.

FIG. 5 is a first graph of binary states classification results.

FIG. 6 is a second graph of binary states classification results.

FIG. 7 is a table of experimental results.

FIG. 8 is a table of appliances and the number of states for each appliance.

FIG. 9 is a first graph of multiple states classification results.

FIG. 10 is a second graph of multiple states classification results.

FIG. 11 is a comparison between binary and multiple state experimental results.

### DESCRIPTION

### 1 Overview

The following is a description of power metering system which is configured to provide information, including the states of appliances and power consumption to a user. In general, a power meter included in the system monitors energy usage at the circuit level and a recognition algorithm infers the state of appliances connected to the circuit based on the monitored energy usage and known patterns of appliance usage. In some examples, the system accepts as inputs a voltage signal, a power factor signal, and/or an apparent power signal. The output of the system is an indication of the current operating state of each of the appliances connected to the circuit as well as the power consumption information of the circuit and each individual appliance connected to the circuit.

It is well known that many appliances include a finite number of operating states and that appliances are often used in a predictable manner. For example, when using a computer, a user may switch on the light in the room first, then power on the computer, and then power on the monitor. The power consumption meter of this application differs from conventional power consumption meters in that it utilizes a number of energy consumption signals in conjunction with such knowledge of patterns of appliance usage (e.g., sequential order and correlation of appliance states) to infer appliance state. Thus, the meter is configured to use a time series probabilistic model to determine the power consumption of each appliance connected to the circuit.

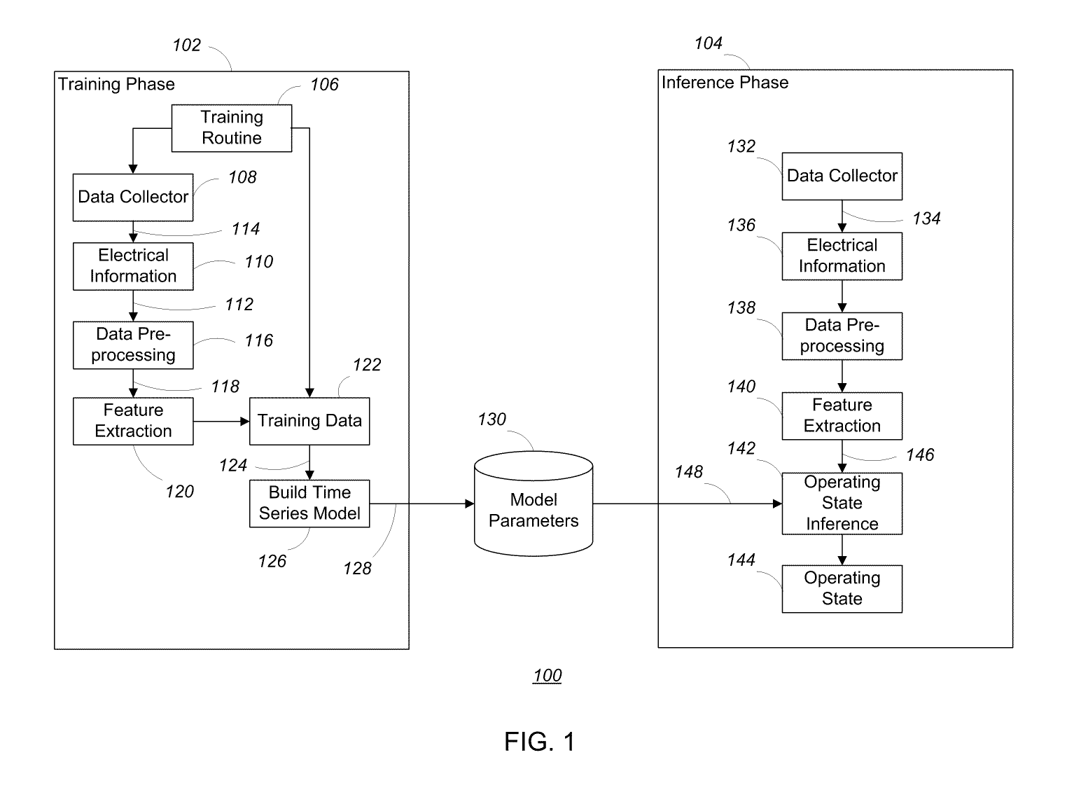

Referring to FIG. 1, a power consumption meter system is first trained during a training phase 102. The training phase 102 is configured to collect power consumption information from a circuit which supplies power to a number of appliances. The collected power consumption information is used by the training phase 102 to build a time series model of power consumption for the circuit. The time series model is utilized by an inference phase 104 to infer (e.g., using a Bayesian filter) the operating state of the appliances connected to the circuit when the appliances are being used in a real-world environment.

### 2 Training Phase

In the training phase 102, each appliance connected to the circuit is known, as are the operating states of each of the appliances. A training routine 106 is created such that a sequence of combinations of operating states of the appliances is executed. The training routine 106 is created such that a variety of different loads, corresponding to different combinations of operating states, are produced on the circuit. In some examples, the sequence of combinations of operating states includes all possible combinations of the states of the appliances connected to the circuit. In other examples, the sequence includes a subset of all possible combinations of the states sufficient to train the power meter. In some examples, the training routine 106 is configured to pause at each combination of operating states for a predetermined period of time (e.g., 5 minutes).

As the training phase 102 executes the training routine 106, a data collector 108 collects measurements of the total power consumption of the circuit (e.g., at the distribution board level). In addition, during the training phase 102, the data collector 104 collects measurements of electrical consumption from appliance level power meters installed at each appliance connected to the circuit.

The power consumption data 114 collected by the data collector 108 is provided to an electrical information module 110. The electrical information module 110 forms a number of measurement signals 112 from the power consumption data 114. In some examples, the measurement signals 112 include a voltage signal, a power factor signal, and an apparent power signal. In some examples, the operating states of the appliances have an unwanted influence on the measurement signals 112 of the circuit. This influence can cause voltage variations which can negatively affect the ability of the meter 100 to recognize appliance operating states. To mitigate this effect, the apparent power of the circuit can be pre-processed by a pre-processing module 116 before any features are extracted. For example, the pre-processing module 116 can normalize the apparent power as follows:

$${P}_{Norm} ( t ) = {( \frac{110}{V ( t )} )}^{2} P ( t ) = {110}^{2} ( \frac{P ( t )}{{V ( t )}^{2}} ) = {110}^{2} \frac{I ( t )}{V ( t )} = \frac{{110}^{2}}{R ( t )} = \frac{{{V}_{Norm} ( t )}^{2}}{R ( t )}$$

The processed measurement signals 118 are passed to a feature extractor 120. In some examples, the feature extractor 120 applies a sliding window to the processed measurement signals 118. The sliding window serves to accumulate power consumption information within a set period of time for the purpose of eliminating noise and preserving information between samples when the sampling rate is low. Factors such as the mean, maximum, minimum, crest factor, etc. are extracted from the accumulated power consumption information, taking the temporal factor of the sliding window into account.

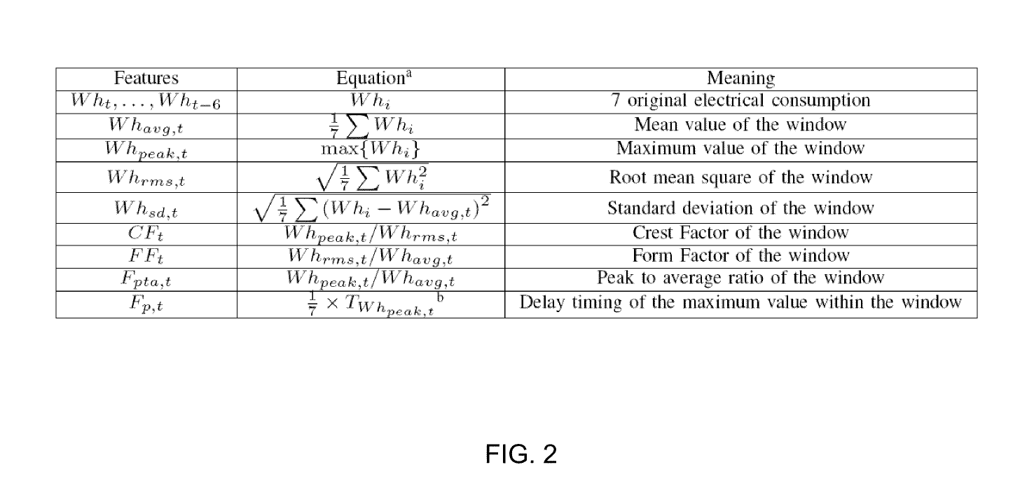

In one example, the window size is 7 samples and the window shifts 1 sample every 5 seconds. Therefore, the content of the window at time t (sometimes referred to as a “time slice”) is O′ₜ={Wₕ_{ₜ}, Wₕ_{ₜ₋₁}, . . . , Wₕ_{ₜ₋₆}}. In this example, the window maintains the 7 most recent records of power consumption information, where Wₕ_{ₜ} is the total power consumption over 5 seconds from time t-1 to t. O′ₜ can also be calculated in several other forms depending on the information that is desired. An exemplary set of features extracted by the feature extraction module 120 is shown in FIG. 2.

The feature extractor 120 discretizes the extracted features by first sorting the values of each extracted feature. The entropy between adjacent values of the features is computed and used to determine “cut points.” A cut point is a value of a feature which is determined to be a dividing line between two operating states. For example, the maximal and minimal apparent power can be used to determine the cut points between different operating states of each appliance. After all cut points are determined, the features are segmented into intervals and indexed.

The features and cut points extracted (which can be referred to as “observation sequences”) using the feature extraction module 120, along with the operating state information used in the training routine 106 are provided to a training data formation module 122. In some examples, the training data formation module 122 forms training data which includes a number of pairs of discretized feature values (determined above) and state vectors (as determined below) as follows:

D={(yₜ,xₜ)}_{T=0}

where y, is a state vector at time slice t and xₜ is the set of discretized feature values at time slice t.

Each state vector represents the state of all appliances within a single time slice. The state vectors can be formed by combining the operating state information and the cut points at each time slice. In some examples, the each state vector in the training data can be represented as a string representing the state of all appliances at a given time slice. Each string includes N digits, where each digit of the string corresponds to one of N appliances and is configured to represent all states of the appliance. The digits can represent binary or multiple operating states. For example, consider a string including 5 appliances, {A₁, A₂ , A₃, A₄, A₅}. Appliances A₁ and A₄ are in operating states 3 and 1 respectively while the other appliances are in the off state (i.e., 0). The resulting training data string is {3,0,0,1,0}. Within this application and without connoting any other meaning, this training data string can be called a “label sequence.” Such label sequences can be used for constructing probabilistic models based on statistics. In particular, the label sequences can be used to build a model such that parameters of an appliance recognition model can be determined in the inference phase 104. Given an observation sequence from a real-world scenario, the model can be applied to infer the operating states of appliances in real-time.

The model is formed by passing the training data 124 to a time series model formation module 126, resulting in a time series model 128. The time series model 128 is determined such that it utilizes correlation between appliance operating states and sequential order of appliance states to improve operating state inference accuracy. In particular, the use of correlation decreases the number of possible state vectors and the sequential order finds the most likely transitions between appliance states. The model parameters of the model 128 determined by the time series model formation module 126 are stored in a model parameter storage device 130 for later use.

### 3 Inference Phase

In the inference phase 104, the time series model 128 determined in the training phase 102 is utilized to infer operating states of appliances connected to a circuit in a real-world environment. During the inference phase, the data collector module 132 does not receive power consumption information from smart meters connected to each appliance. Instead, the only data collected is the total power consumption at the circuit level.

The power consumption data 134 collected by the data collection module 132 is processed by an electrical information module 136, a data pre-processing module 138, and a feature extraction module 140 in much the same way as was described above in relation to the training phase 102.

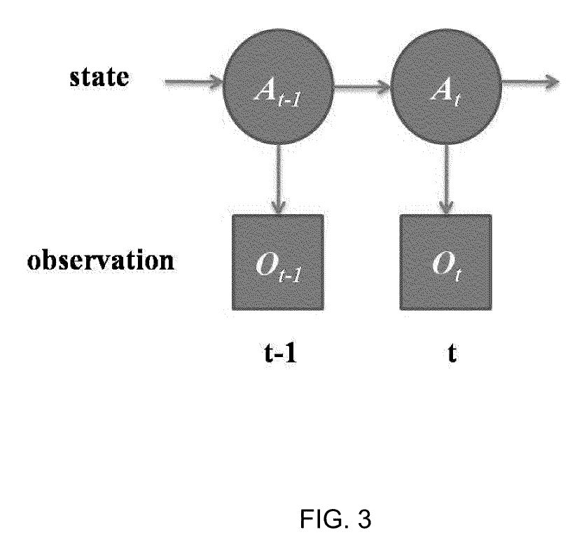

The extracted features 146 and the previously determined model parameters 148 are passed to an operating state inference module 142. The operating state inference module 142 is configured to use the model parameters 148 and the extracted features 146 to recognize patterns for using appliances. One example of such a pattern is when a person is preparing a meal, they takes food from a refrigerator, and then heat the food using a microwave. The order of using appliances is relevant to user behavior and the position of appliances in the house. If the user has a regular lifestyle, the pattern is likely to be regular. One suitable method for solving such an inference problem is to use a Dynamic Bayesian Network (DBN), for example, as shown in FIG. 3.

Given the above, the parameters that need to be learned are the probability distributions P(A^{j}|Aⁱ) and P(O|Aⁱ) for all Aⁱ, where Aⁱ and A^{j} are the combinations of appliance states. p(A^{j}|Aⁱ) is the probability of transition from state Aⁱ to A^{j}, which is called transition model. It needs to calculate the ratio of all possible states transition from Aⁱ. However, the observation model P(O|Aⁱ), which is the probability of observing O at state Aⁱ, is more complicated than the transition model, because the observations O are continuous which cannot simply be calculated by counting. Two methods can be used to handle the observation model. In the first method, a range of numeric attributes is discretized into nominal attributes. The method uses an entropy minimization heuristic to discretize continuous-valued attributes into multiple intervals. After that, P(O|Aⁱ) can easily be computed by P(O_{d}|Aⁱ), where O_{d} is a discrete value calculated from O.

$$p ( {O}_{d} \vert {A}^{i} ) = \frac{number of instances observed {O}_{d} in {A}^{i}}{number of instances in {A}^{i}}$$

In the second method, mixture of Gaussian distributions is adopted to estimate p(O|Aⁱ). For example, for each state, 5 Gaussian distributions are used to approximate p(O|Aⁱ). That is,

$$p ( O \vert {A}^{i} ) = {\sum }_{k = 1}^{5} {c}_{ik} N ( O ; {μ}_{ik} , {Σ}_{ik} )$$

where cᵢₖ, Σᵢₖ, and μᵢₖ are the weight, covariance matrix and mean vector of the k-th Gaussian component respectively, and

$${\sum }_{k = 1}^{5} {c}_{ik} = 1$$

Therefore, all that needs to be learned are the weights cᵢₖ, mean vectors μᵢₖ, and covariance matrix Σᵢₖ for all i, k. For calculating these parameters, k-means are used, where k=5 to generate 5 clusters for each Aⁱ. Then, μᵢₖ and Σᵢₖ are computed from a corresponding cluster. Finally, weight cᵢₖ can be computed from the ratio of the number of instances in k-th cluster to all instances in Aⁱ.

A Bayesian filter is used to solve this problem. Bayesian filters can compute p(Aₜ|O_{1:t-1}), which is the posterior distribution over the current state given all observations to date, where O_{1:t} is the set of observations up to time t. Here we want to estimate this conditional probability and assign the state with the maximal probability as the prediction at time t. By the Bayes' rule and the Markov property, the conditional probability can be written as:

$$\begin{matrix}p ( {A}_{t} \vert {O}_{1 : t} ) = ( \frac{p ( {O}_{t} \vert {A}_{t} ) p ( {A}_{t} \vert {O}_{1 : t - 1} )}{p ( {O}_{t} \vert {O}_{1 : t - 1} )} ) & ( 1 a ) \\ = \frac{p ( {O}_{t} \vert {A}_{t} ) {\sum }_{{A}_{t - 1}} p ( {A}_{t} \vert {A}_{t - 1} ) p ( {A}_{t - 1} \vert {O}_{1 : t - 1} )}{p ( {O}_{t} \vert {O}_{1 : t - 1} )} & ( 1 b )\end{matrix}$$

where

$$p ( {O}_{t} \vert {O}_{1 : t - 1} ) = {\sum }_{{A}_{t}} p ( {O}_{t} \vert {A}_{t} ) p ( {A}_{t} \vert {O}_{1 : t - 1} )$$

is the normalized term of (1a). According to (1b), the state transition probability (Aₜ|Aₜ₋₁), and the observation probability p(Oₜ|Aₜ) can be estimated. The state with maximal posterior probability is the status at time t.

### 4 Experimental Results

Smart meters called PA-310 were deployed to monitor the total electrical consumption in a living laboratory. The meters were installed on the distribution board. In other words, there is no need to install them everywhere. The total electrical consumption from the distribution boards was measured every 5 seconds in the experiments.

In the experiment there were 3 PA-310 power meters, 4 distribution boards, and a server at the electrical room. First, current transformers were installed on circuits which supply electricity for the experiment environment. Each meter contains 3 current transformers. Every PA-310 power meter could monitor up to 3 circuits simultaneously. Then, electrical consumption was sent to the server via serial port.

Two experiments were designed to evaluate the approach, including binary states classification and multiple states classification. The Bayesian filter was compared with three non-temporal models, which are KNN, Naive Bayes, and SVM. In addition, the Bayesian filter was compared with Viterbi algorithm to verify the difference between online and offline inference approach. To evaluate the approach, four criteria were used. First, the overall accuracy (OA) shows the accuracy of entire state combinations. It is defined as:

$$O A = \frac{1}{T} {\sum }_{t = 1}^{T} δ ( {g}_{t} = {p}_{t} )$$

where gₜ and pₜ are the states combination of ground truth and the prediction result at time t, respectively. Next, the average appliance accuracy (AAA) was computed, which represents the mean accuracy of each appliance. In addition, average appliance recall (AAR) can exhibit the correctness of each appliance that is in use. In other words, it shows the accuracy of rarely operating appliances, such as microwave or oven. They are defined as following,

$$A A A = \frac{1}{N} {\sum }_{n = 1}^{N} accuracy of appliance n$$

$$A A R = \frac{1}{N} {\sum }_{n = 1}^{N} recall of appliance n$$

where N is the number of appliances. Finally, word error rate (WER) displays the error rate of state transition sequences between ground truth and prediction results. It can be computed as,

$$WER = \frac{{\sum }_{n = 1}^{N} MED ( {G}_{s}^{n} , {P}_{s}^{n} )}{{\sum }_{n = 1}^{N} length of {G}_{s}^{n}}$$

Gₛⁿ and Pₛⁿ are the “segment sequences” of ground truth and prediction, respectively. The definition of the segment sequence is that sequential and identical states are treated as one segment, for example, if the ground truth of the monitor is 001111100, Gₛⁿ will be 010. Similarly, if the prediction result is 001010100, Pₛⁿ will be 0101010. The MED(Gₛⁿ, Pₛⁿ) is the minimum edit distance between Gₛⁿ and Pₛⁿ.

### 4.1 Binary States Classification

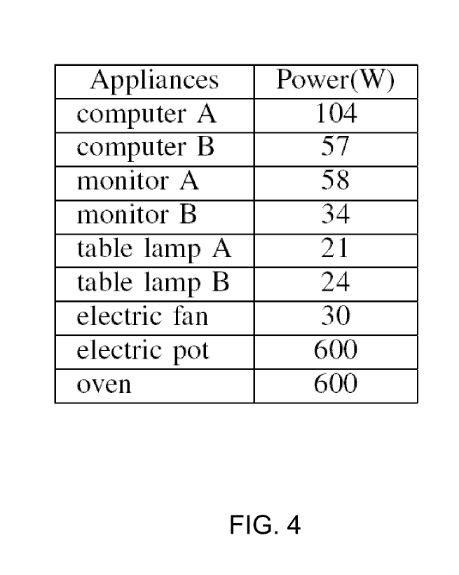

In this experiment, it is assumed that all appliances controlled by binary states, on and off Two scripts were designed to collect training and testing data. The appliances in the experiment are shown in FIG. 4.

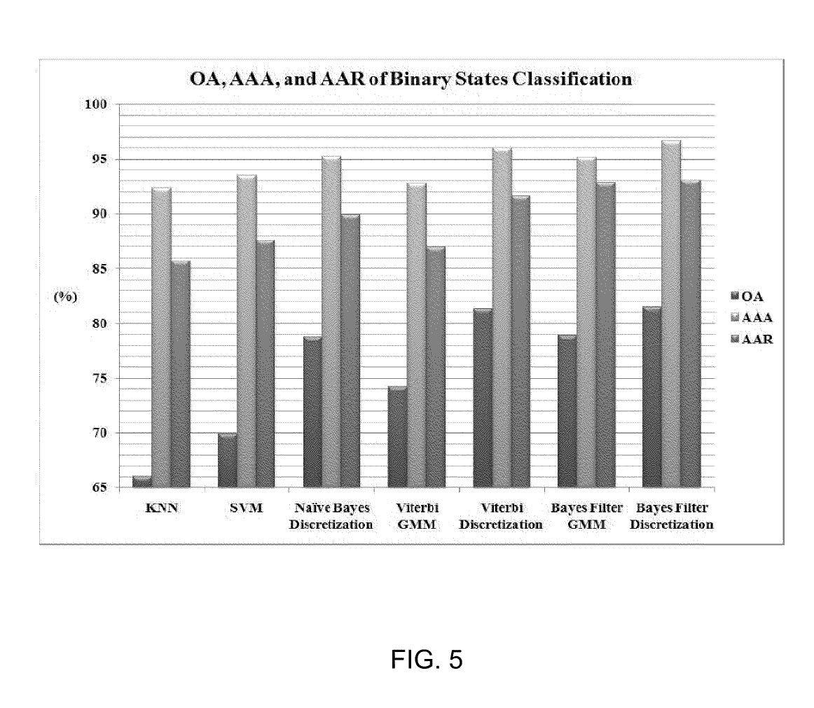

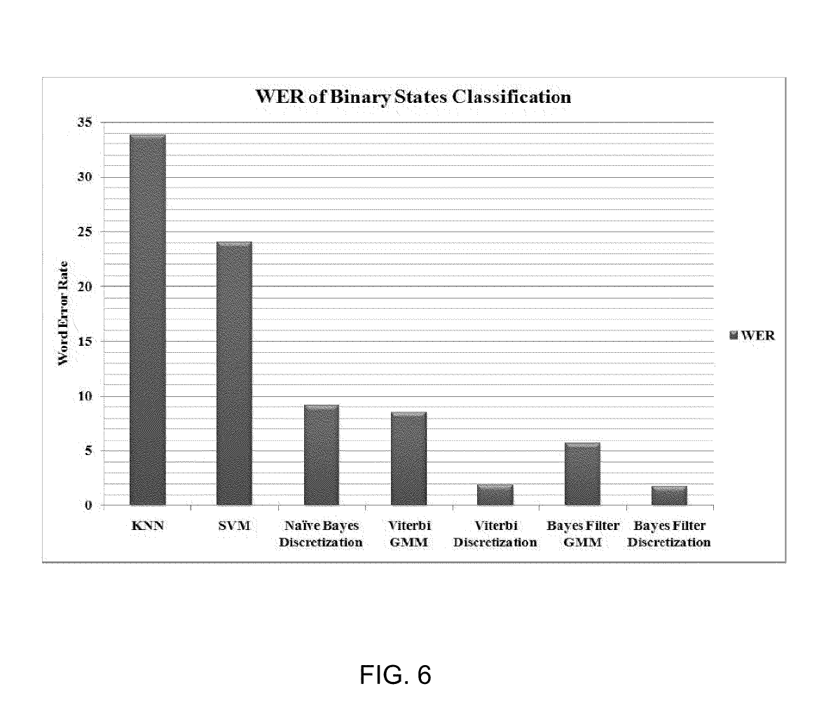

The scripts both contain 26 events of states change and 17 combinations of operating states. When collecting training data, the sate of an appliance is changed every 5 minutes regularly for 2 hours and 15 minutes. Also, when collecting testing data, the real situation is simulated, the duration of each state is not restricted to 5 minutes, but depends on the use of each appliance. For example, food is heated for 30 minutes by oven and then the monitor is switched off immediately after a computer is shut down. The phase takes 4 hours. FIGS. 5 and 6 show the results of several classifiers.

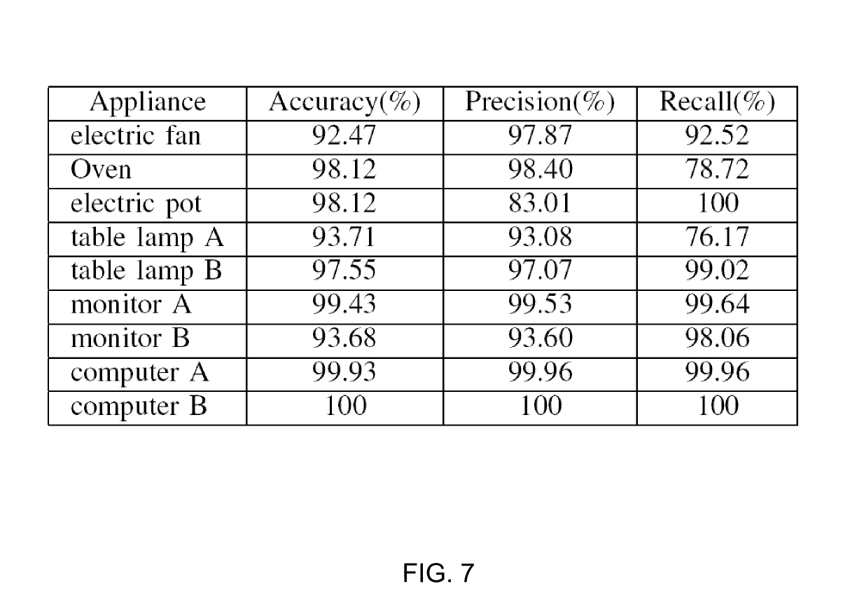

The figures reveal that the Bayesian filter is more accurate than non-temporal models, especially on WER. In addition, the results show that constructing the observation model with discretized features contributes the best performance. The results of each appliance recognized by Bayesian filter and discretization methods are shown in FIG. 7.

The figure reveals that most appliances can be accurately recognized. In brief, using discretization to build the observation model and employing Bayesian filter to infer the current state is a better approach for recognizing the binary states of appliances.

### 4.2 Multiple States Classification

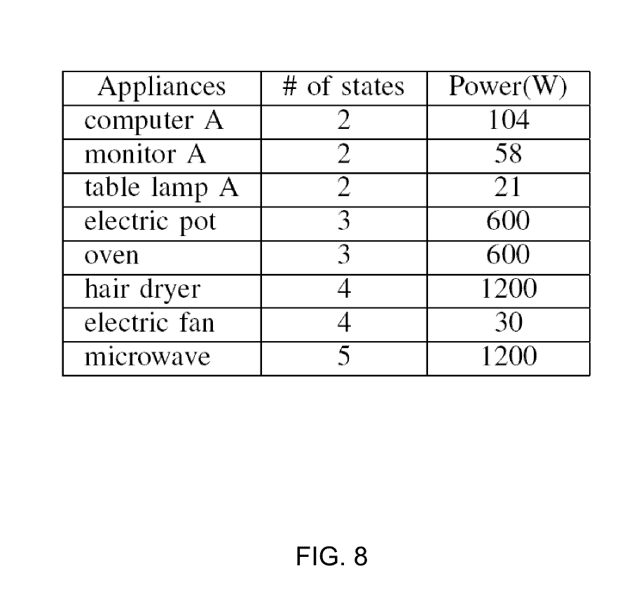

Referring to FIG. 5, the AAA and AAR of the Bayesian filter approach are greater than 93%, which enables recognition the more detailed states of appliances. Hence, multiple operating states are defined for each appliance. For instance, there are three operating states of electric pot: not in use, keeping warm, and heating. FIG. 8 lists the number of states of each appliance used in this experiment.

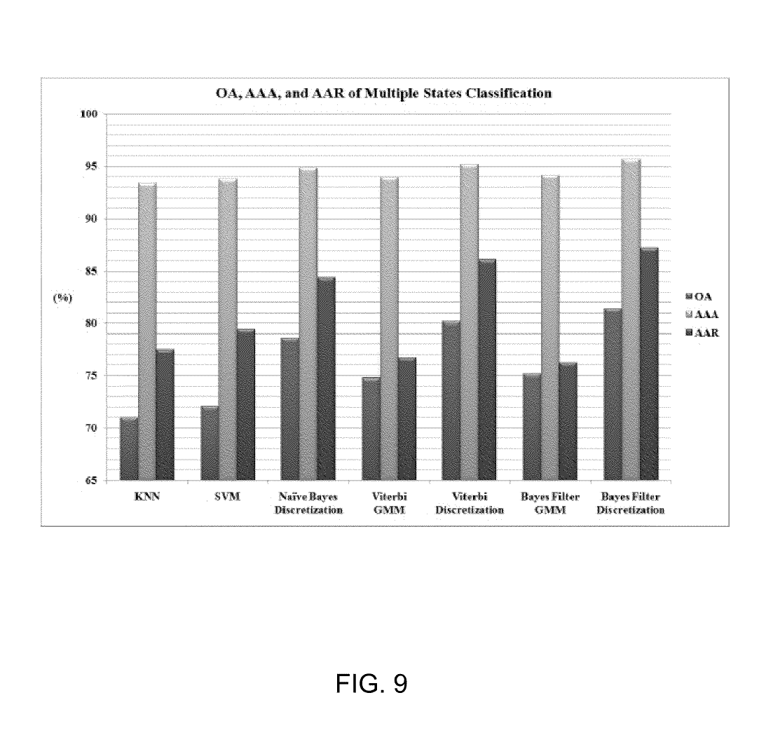

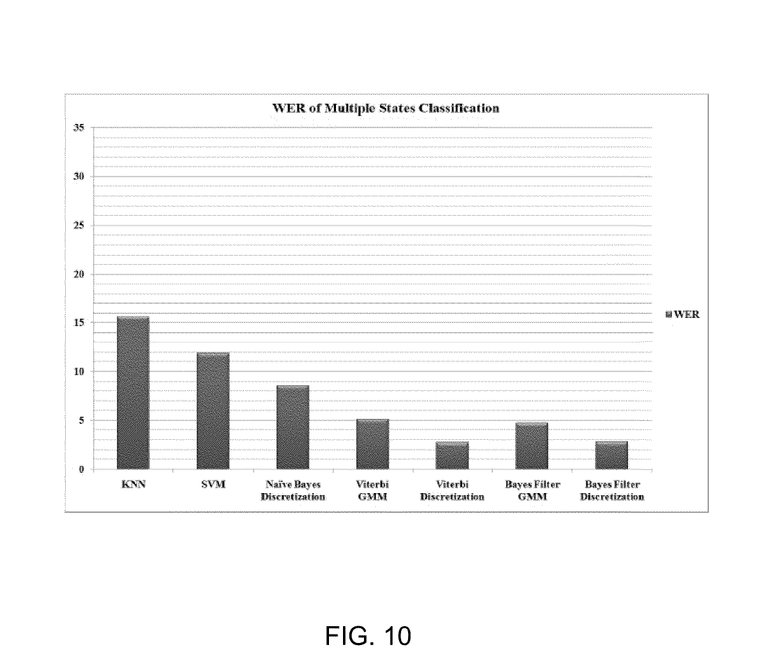

In this experiment, there is only one subject. Therefore, computer B, monitor B, and lamp B were removed. Furthermore, a microwave and a hair dryer are added. A subject was asked to use the appliances with their own habits and two data sets were collected. Therefore, it can be verified whether user behavior is helpful. Moreover, the duration of using each appliance was not restricted when collecting data. The two data sets consist of 18 combinations of states and 48 state changes, both of which are about 3 hours. We perform 2-fold cross-validation to compare the performance of the approach with those non-temporal models and Viterbi algorithm. The results shown in FIGS. 9 and 10 exhibit that Bayesian filter has the best performance.

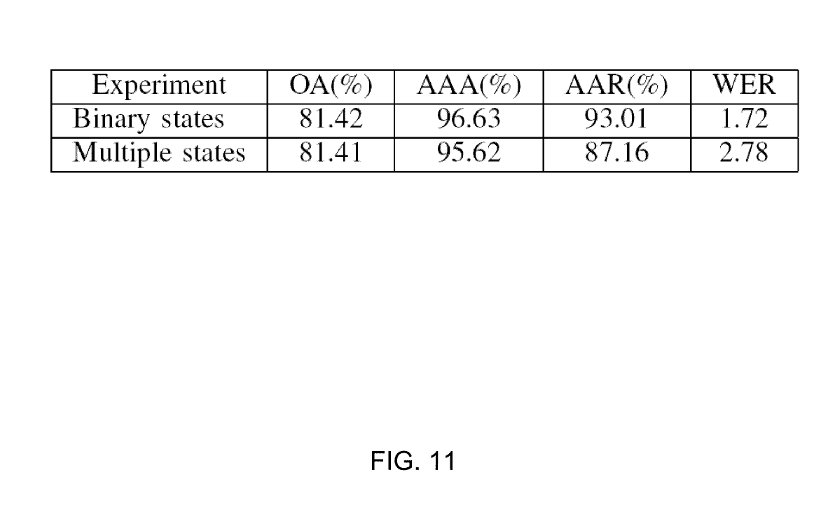

However, taking GMM to approximate the observation model gets worse results than discretization. GMM cannot distinguish between the state combinations with similar power consumption well. In the experimental setting, there are several states with similar consumption, for example, the power consumption of the 3 wind settings of electric fan and the keeping warm state of electric pot are very close to 28 W. For distinguishing such states, discretization is much better than GMM. Besides, Bayesian filter with discretization method still outperforms those non-temporal models. FIG. 11 shows the comparison between the results of binary states and multiple states classification using Bayesian filter with discretization method.

Although there are several states with similar consumption in multiple states classification, the results of multiple states experiment are slightly worse than binary states. This fact shows that our approach can still recognize detailed operating states of several appliances.

It is to be understood that the foregoing description is intended to illustrate and not to limit the scope of the invention, which is defined by the scope of the appended claims. Other embodiments are within the scope of the following claims.

What is claimed is:

1. A method for recognizing appliance operating states comprising:
accepting measurement features characterizing power utilization by a plurality of appliances, at least some of the appliances having a plurality of operating states;
accepting data including data characterizing sequential use of the appliances, and data characterizing an association of features characterizing power consumption with operating states of the appliances; and
determining a temporal sequence of operating states of the appliances from the accepted measurements using the accepted data.

2. The method of claim 1 wherein the measurement features characterizing power utilization comprise features characterizing power consumption.

3. The method of claim 2 wherein the accepted features characterizing power consumption comprise a temporal sequence of total power consumption.

4. A power meter comprising an appliance recognition module configured to
accept measurement features characterizing power utilization by a plurality of appliances, at least some of the appliances having a plurality of operating states;
accept data including data characterizing sequential use of the appliances, and data characterizing an association of features characterizing power consumption with operating states of the appliances; and
determine a temporal sequence of operating states of the appliances from the accepted measurements using the accepted data.

5. A power meter configured to recognize appliance operating states of a plurality of appliances, the power meter comprising:
an appliance recognition component including,
a training component configured to determine model parameters based on training input and data characterizing power utilization;
a storage for the model parameters; and
an inference component configured to use the model parameters to determine a temporal sequence of operating states of the appliances;
wherein the model parameters characterize sequential use of the appliances and an association of data characterizing power consumption with operating states of the appliances.

6. The method of claim 5 wherein the measurement features characterizing power utilization comprise features characterizing power consumption.

7. The method of claim 6 wherein the accepted features characterizing power consumption comprise a temporal sequence of total power consumption.

8. The method of claim 5 wherein the power meter is further configured to determine data characterizing the power consumption of each appliance of the plurality of appliances.

9. The method of claim 5 wherein the model parameters characterize a model of power consumption for a circuit.

10. The method of claim 9 wherein the inference component applies Bayesian probability techniques to the model to determine the temporal sequence of the operating states of the appliances.

11. The method of claim 10 wherein the Bayesian probability techniques include a Dynamic Bayesian Network.

12. The method of claim 5 wherein the training input includes a sequence of combinations of appliance operating states which is executed by the training component.
